(19) United States
(12) Patent Application Publication
(10) Pub. No.: US 2026/0089938 A1
(43) Pub. Date: Mar. 26, 2026

(54) MEMORY DEVICES WITH DIFFERENT CONDUCTIVE TYPES AND METHODS FOR MANUFACTURING THE SAME

(71) Applicant: Taiwan Semiconductor Manufacturing Company, Ltd., Hsinchu (TW)

(72) Inventors: Bo-Wei Wu, Hsinchu City (TW); Chia-En Huang, Hsinchu City (TW); Pin-Dai Sue, Hsinchu City (TW); Jung-Hsuan Chen, Hsinchu City (TW); Ting-Wei Chiang, Hsinchu City (TW)

(73) Assignee: Taiwan Semiconductor Manufacturing Company, Ltd., Hsinchu (TW)

(21) Appl. No.: 18/892,861

(22) Filed: Sep. 23, 2024

(51) Int. Cl. H10B 20/00; G11C 5/06

(52) U.S. Cl. CPC H10B 20/65; G11C 5/063; H10B 20/30

(57) ABSTRACT

A memory device includes a first portion of a memory array comprising a plurality of first read only memory (ROM) cells, each of the plurality of first ROM cells comprising a first transistor that has a first conductive type and electrically coupled to a first word line and a first bit line. The memory device includes a second portion of the memory array comprising a plurality of second ROM cells, each of the plurality of second ROM cells comprising a second transistor that has a second conductive type and electrically coupled to a second word line and a second bit line. The first word line and second word line extend along a first lateral direction, and the first bit line and second bit line extend along a second lateral direction perpendicular to the first lateral direction.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example block diagram of a memory device, in accordance with some embodiments.

FIGS. 2, 3, 4, 5, 6, 7, 8, and 9, illustrate various arrangements of a memory array of the memory device of FIG. 1, respectively, in accordance with some embodiments.

FIG. 10 illustrate a flow chart of an example method for forming a memory device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Read only memory (ROM) arrays are semiconductor memory chip arrays with data permanently stored in the array. ROM arrays are made up of a number of ROM cells, each ROM cell including a transistor in an “on” or “off” state. Each ROM cell is configured to store a (e.g., binary) data bit reflecting that on or off state. In the existing technologies, the ROM cells of a ROM array (or the respective transistors of the ROM array) are typically formed with the same conductive type, e.g., n-type, in the interest of performance. However, with all n-type transistors formed on a substrate, a variety of processing or manufacturing issues arise such as, for example, an uneven n-type and p-type pattern distribution across the whole substrate which disadvantageously result in polishing issues. Thus, the existing ROM devices/arrays have not been entirely satisfactory in certain aspects.

The present disclosure provides various embodiments of a memory device (e.g., a memory array) including a plural number of ROM cells with an even n-type/p-type distribution. For example, a first group of the ROM cells may be formed in n-type and a second group of the ROM cells may be formed in p-type, where the first group of ROM cells and the second group of ROM cells can be evenly distributed across a substrate. In one aspect, some of the n-type ROM cells (constituting respective subsets of the first group) and some of the p-type ROM cells (constituting respective subsets of the second group) may be alternately arranged along a first lateral direction, which can be the lengthwise direction of word lines (WLs) of the memory array. In another aspect, all the n-type ROM cells (constituting the first group) and all the p-type ROM cells (constituting the second group) may be disposed next to each other along the first lateral (WL) direction. Further, disposed next to each of the first group (n-type) of ROM cells or second group (p-type) of ROM cells along a second lateral direction perpendicular to the first lateral direction, a corresponding number of input/output (I/O) circuits that have the same conductive type can be formed. With such an arrangement, the ROM cells of the disclosed memory device can be free from the above-identified manufacturing issues, which can advantageously lead to a higher yield for manufacturing the memory device.

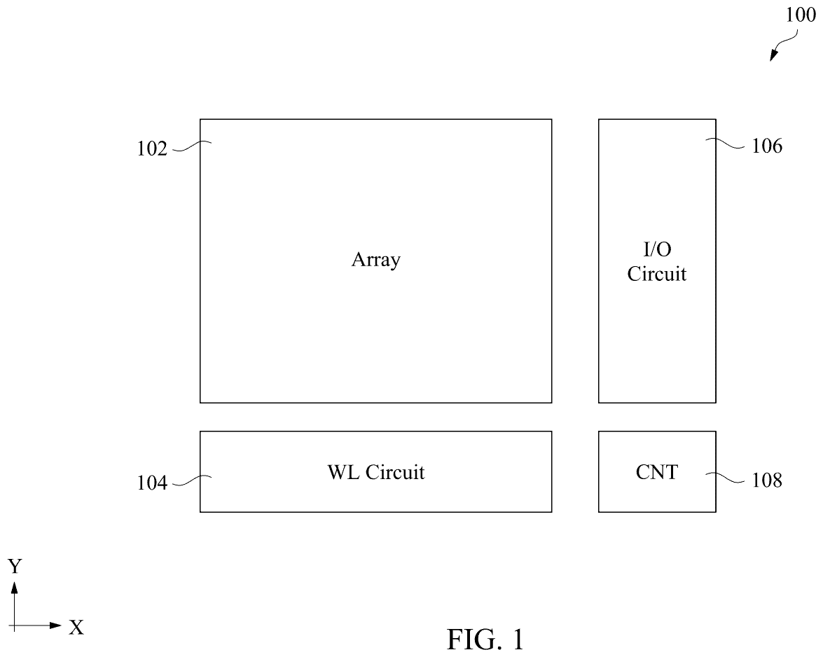

FIG. 1 illustrates a block diagram of an example memory device (or circuit) 100, in accordance with various embodiments. The memory device 100 can include a storage device configured to be connected to an external host device (not illustrated). It should be appreciated that the memory device 100, as shown in FIG. 1, is a simplified example, and thus, the memory device 100 can include any of various other components while remaining within the scope of the present disclosure.

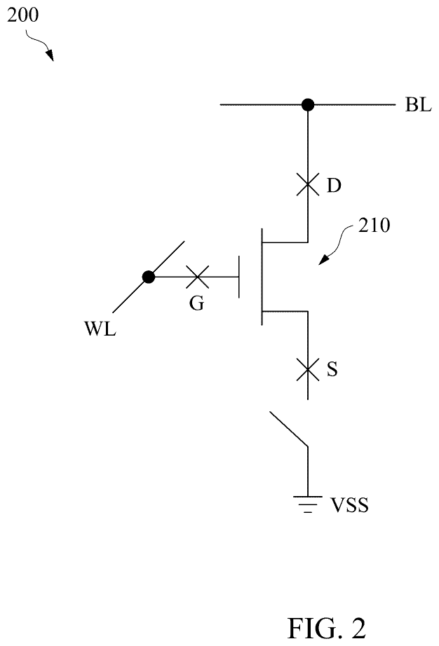

As shown in the example of FIG. 1, the memory device 100 includes a memory array 102, a word line (WL) circuit 104, an input/output (I/O) circuit 106, and a controller (or logic control circuit) 108. In some embodiments, the controller 108 can be operatively coupled to a memory controller (not shown) through BUS, which may transmit and/or receive data based on an interface. The memory device 100 is a memory that stores data. The memory array 102 includes a number of memory sub-arrays or memory banks. Each of the memory sub-arrays/banks includes a plural number of memory cells. In some embodiments, the memory cells may each include a read only memory (ROM) cell, which may be formed of one or more transistors (e.g., ROM cell 200 of FIG. 2). The memory array 102 can be formed as a (e.g., two-dimensional or three-dimensional) array having a plural number of rows and a plural number of columns, each of the ROM cells disposed at the intersection of a corresponding row and a corresponding column. Further, the memory array 102 can include a number of word lines (WLs) respectively disposed along the rows and a number of bit line (BLs) respectively disposed along the columns. However, it should be understood that the memory array 102 can include a plural number of any other memory cells, while remaining within the scope of the present disclosure.

The controller 108 can provide address information (ADD) to the WL circuit 104 and/or the I/O circuit 106. The ADD at least includes, for example, a row address (RAd) and a column address (CAd). In some embodiments, the row address RAd and the column address CAd may be used to select a WL and a BL, respectively. For example, the WL circuit 104 can include a WL (or row) decoder and one or more row multiplexers; and the I/O circuit 106 can include a BL keeper circuit, a BL pre-charge circuit, a BL (or column) decoder, one or more column multiplexers, an output latch, a design for testability/test (DFT) circuit, and a buffer.

The WL circuit 104 can receive the row address (RAd) from the controller 108. Based on the row address (RAd), the WL circuit 104, which may include or be integrated with a driver (circuit), is configured to access a corresponding WL. The WL circuit 104 can apply a generated voltage to a corresponding access line (e.g., a WL) based on, for example, the RAd. For example, one of the WLs may be selected by the WL circuit 104 through three decoding stages: predecode, decode, and postdecode. The predecode stage determines which of a potentially hierarchical set of memory blocks contains the data, and recode address bits to reduce the fanout to the word line decoders of a single block. One or more word line decoders will respond to an address. The postdecode stage can then select a single WL. In some embodiments, the WL circuit 104 can be implemented by a collection of 2^{M} logic gates (e.g., NAND gates, NOR gates, etc.) organized in a regular, dense fashion.

The I/O circuit 106 can receive the column address (CAd) from the controller 108. Based on the column address (CAd), the I/O circuit 106, which may include or be integrated with a column decoder, is configured to access a corresponding BL. For example, prior to accessing (reading) one of the ROM cells through a corresponding BL, the BL pre-charge circuit of the I/O circuit 106 can pre-charge the BLs of the memory array 102 to a logic high state, which can be maintained by the BL keeper circuit. Next, based on the column address (CAd), one of the BLs is selected. Concurrently with, or subsequently to the corresponding WL selected based on the row address (RAd), at least one of the ROM cells of the memory array 102 can be selected based on the row address (RAd) and column address (CAd), and a logic state of the selected ROM cell can be read out by the I/O circuit 106. For example, the I/O circuit 106 can receive a small signal from the selected ROM cell and amplify it to a large signal, thereby differentiating a logic state of the data stored in the selected ROM cell.

In some embodiments, the memory array 102, the WL circuit 104, the I/O circuit 106, and the controller 108 may be physically arranged in the configuration shown in FIG. 1. For example, the WL circuit 104 is disposed next the memory array 102 along the Y-direction, which can be the lengthwise direction of WLs of the memory array 102, and the I/O circuit 106 is disposed next the memory array 102 along the X-direction, which can be the lengthwise direction of BLs of the memory array 102. Further, the ROM cells of the memory array 102 can include a first group of ROM cells in n-type, each with a corresponding portion of the I/O circuit 106 formed in the same conductive type (n-type) and disposed next to itself along the X-direction, and a second group of ROM cells in p-type, each with a corresponding portion of the I/O circuit 106 formed in the same conductive type (p-type) and disposed next to itself along the X-direction, which will be discussed below.

FIG. 2 illustrates an example circuit diagram of a single ROM cell 200, in accordance with some embodiments. A plural number of such ROM cells 200 can be arranged as the memory array 102 shown in FIG. 1. Although the ROM cell 200 of FIG. 2 includes one transistor, it should be understood that the circuit diagram of FIG. 2 is provided for illustrative purposes and is not intended to limit the scope of the present disclosure. Accordingly, the ROM cell 200 shown in FIG. 2 can include any of various other components (e.g., one or more additional transistors), while remaining within the scope of the present disclosure.

As shown, the ROM cell 200 includes one transistor 210 having a gate terminal, a first source/drain terminal, and a second source/drain terminal. The gate terminal is connected to a word line (WL), the drain terminal is connected to a bit line (BL), and the source terminal is selectively connected to a supply voltage, e.g., a ground voltage (VSS). In some embodiments, whether the ROM cell 200 is in a logical “1” or “0” state can depend on whether the second source/drain terminal of the transistor 210 is connected to the VSS. For example, when the second source/drain terminal is connected to the VSS, the ROM cell 200 presents a logical 1; and when the second source/drain terminal is disconnected from the VSS, the ROM cell 200 presents a logical 0. In some other embodiments (not shown in FIG. 2), whether the ROM cell 200 is in a logical “1” or “0” state can depend on whether the first source/drain terminal of the transistor 210 is connected to the BL. For example, when the first source/drain terminal is connected to the BL, the ROM cell 200 presents a logical 1; and when the first source/drain terminal is disconnected from the BL, the ROM cell 200 presents a logical 0.

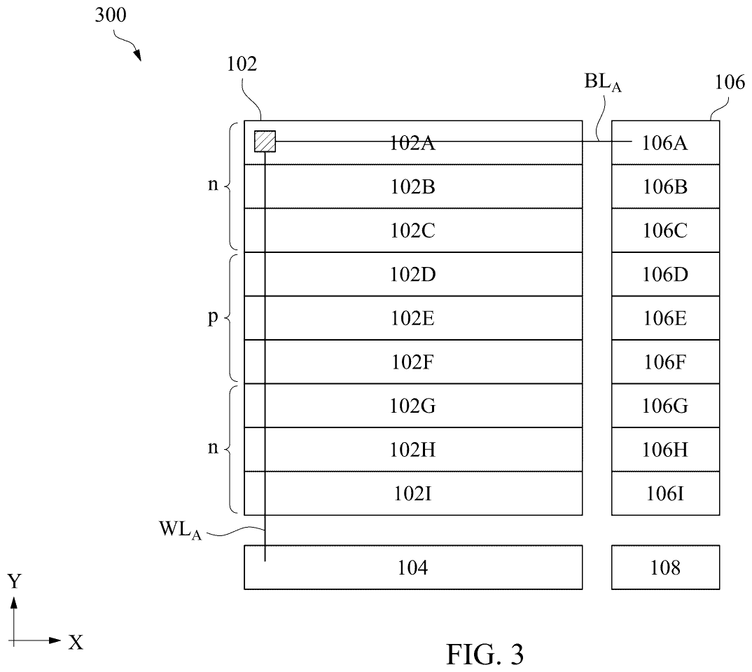

FIGS. 3, 4, and 5 illustrate various layouts or arrangements, 300, 400, and 500, of the ROM cells of the memory array 102, respectively, in accordance with various embodiments. In general, each of the arrangements 300 to 500 includes respective floorplans for forming a plural number of n-type ROM cells and a plural number of p-type ROM cells along a substrate, according to various embodiments of the present disclosure. It should be understood that the arrangements of FIGS. 3-5 are merely provided for illustrative purposes and are not intended to limit the scope of the present disclosure.

In FIG. 3, the memory array 102 (or its floorplan) can be divided into array sections 102A, 102B, 102C, 102D, 102E, 102F, 102G, 102H, and 102I, and the I/O circuit 106 (or its floorplan) can be divided into I/O sections 106A, 106B, 106C, 106D, 106E, 106F, 106G, 106H, and 106I. In some embodiments, the I/O sections 106A to 106I are (e.g., physically) disposed next to the array sections 102A to 102I along the X-direction, respectively, and the physically aligned array section and I/O section are formed with the same conductive type. For example, the I/O section 106A is physically aligned with the array section 102A along the X-direction, and the ROM cells formed in the array section 102A and the transistors formed in the I/O section 106A have the same conductive type. Further, the ROM cells formed in each of the array sections 102A to 102I are electrically coupled to a corresponding aligned one of the I/O sections 106A to 106I through at least one BL (e.g., BL_{A}), and are electrically coupled to the WL circuit 104 through at least one WL (e.g., WL_{A}). The BL may extend along the X-direction, and the WL may extend along the Y-direction.

In some embodiments, the ROM cells in the array sections 102A to 102C and the transistors in the corresponding I/O sections 106A to 106C are each formed with n-type; the ROM cells in the array sections 102D to 102F and the transistors in the corresponding I/O sections 106D to 106F are each formed with p-type; and the ROM cells in the array sections 102G to 102I and the transistors in the corresponding I/O sections 106G to 106I are each formed with n-type. In some embodiments, transistors of the WL circuit 104 disposed immediately next to the memory section 102I (along the Y-direction) and the controller 108 disposed immediately next to the I/O section 106I (along the Y-direction) are formed with n-type. Stated another way, the respective portions of the memory array 102 and the I/O circuit 106 disposed immediately next to the WL circuit 104 and controller 108 can have their transistors formed with the same conductive type.

Although only one memory array and its corresponding WL circuit, I/O circuit, and controller are shown, it should be understood that the arrangement 300 can be generalized to include multiple memory arrays (and corresponding circuits). In such embodiments, another memory array, with the similar arrangement to the memory array 102, can be disposed opposite the I/O circuit 106 shown in FIG. 3 from the memory array 102 shown in FIG. 3. Accordingly, its corresponding I/O circuit can be disposed opposite the other memory array from the I/O circuit 106 shown in FIG. 3.

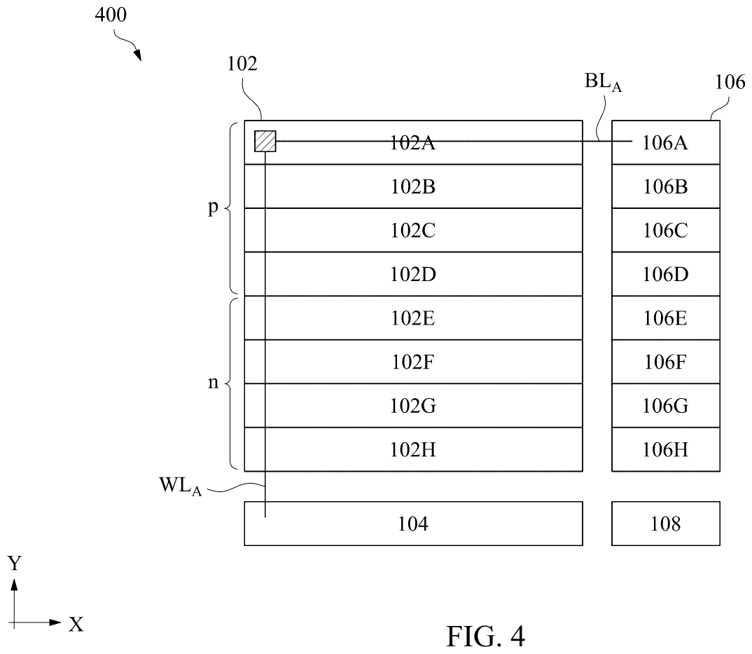

In FIG. 4, the memory array 102 (or its floorplan) can be divided into array sections 102A, 102B, 102C, 102D, 102E, 102F, 102G, and 102H, and the I/O circuit 106 (or its floorplan) can be divided into I/O sections 106A, 106B, 106C, 106D, 106E, 106F, 106G, and 106H. In some embodiments, the I/O sections 106A to 106H are (e.g., physically) disposed next to the array sections 102A to 102H along the X-direction, respectively, and the physically aligned array section and I/O section are formed with the same conductive type. For example, the I/O section 106A is physically aligned with the array section 102A along the X-direction, and the ROM cells formed in the array section 102A and the transistors formed in the I/O section 106A have the same conductive type. Further, the ROM cells formed in each of the array sections 102A to 102I are electrically coupled to a corresponding aligned one of the I/O sections 106A to 106I through at least one BL (e.g., BL_{A}), and are electrically coupled to the WL circuit 104 through at least one WL (e.g., WL_{A}). The BL may extend along the X-direction, and the WL may extend along the Y-direction.

In some embodiments, the ROM cells in the array sections 102A to 102D and the transistors in the corresponding I/O sections 106A to 106D are each formed with p-type; and the ROM cells in the array sections 102E to 102H and the transistors in the corresponding I/O sections 106E to 106H are each formed with n-type. In some embodiments, transistors of the WL circuit 104 disposed immediately next to the memory section 102H (along the Y-direction) and the controller 108 disposed immediately next to the I/O section 106H (along the Y-direction) are formed with n-type. Stated another way, the respective portions of the memory array 102 and the I/O circuit 106 disposed immediately next to the WL circuit 104 and controller 108 can have their transistors formed with the same conductive type.

Although only one memory array and its corresponding WL circuit, I/O circuit, and controller are shown, it should be understood that the arrangement 400 can be generalized to include multiple memory arrays (and corresponding circuits). In such embodiments, another memory array, with the similar arrangement to the memory array 102, can be disposed opposite the I/O circuit 106 shown in FIG. 4 from the memory array 102 shown in FIG. 4. Accordingly, its corresponding I/O circuit can be disposed opposite the other memory array from the I/O circuit 106 shown in FIG. 4.

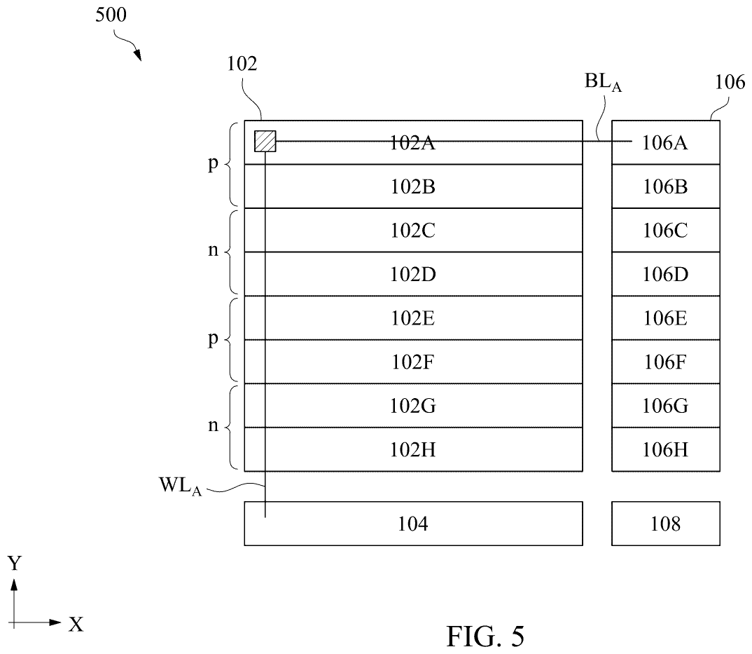

In FIG. 5, the memory array 102 (or its floorplan) can be divided into array sections 102A, 102B, 102C, 102D, 102E, 102F, 102G, and 102H, and the I/O circuit 106 (or its floorplan) can be divided into I/O sections 106A, 106B, 106C, 106D, 106E, 106F, 106G, and 106H. In some embodiments, the I/O sections 106A to 106H are (e.g., physically) disposed next to the array sections 102A to 102H along the X-direction, respectively, and the physically aligned array section and I/O section are formed with the same conductive type. For example, the I/O section 106A is physically aligned with the array section 102A along the X-direction, and the ROM cells formed in the array section 102A and the transistors formed in the I/O section 106A have the same conductive type. Further, the ROM cells formed in each of the array sections 102A to 102I are electrically coupled to a corresponding aligned one of the I/O sections 106A to 106I through at least one BL (e.g., BL_{A}), and are electrically coupled to the WL circuit 104 through at least one WL (e.g., WL_{A}). The BL may extend along the X-direction, and the WL may extend along the Y-direction.

In some embodiments, the ROM cells in the array sections 102A and 102B and the transistors in the corresponding I/O sections 106A and 106B are each formed with p-type; the ROM cells in the array sections 102C and 102D and the transistors in the corresponding I/O sections 106C and 106D are each formed with n-type; the ROM cells in the array sections 102E and 102F and the transistors in the corresponding I/O sections 106E and 106F are each formed with p-type; and the ROM cells in the array sections 102G and 102H and the transistors in the corresponding I/O sections 106G and 106H are each formed with n-type. In some embodiments, transistors of the WL circuit 104 disposed immediately next to the memory section 102H (along the Y-direction) and the controller 108 disposed immediately next to the I/O section 106H (along the Y-direction) are formed with n-type. Stated another way, the respective portions of the memory array 102 and the I/O circuit 106 disposed immediately next to the WL circuit 104 and controller 108 can have their transistors formed with the same conductive type.

Although only one memory array and its corresponding WL circuit, I/O circuit, and controller are shown, it should be understood that the arrangement 400 can be generalized to include multiple memory arrays (and corresponding circuits). In such embodiments, another memory array, with the similar arrangement to the memory array 102, can be disposed opposite the I/O circuit 106 shown in FIG. 5 from the memory array 102 shown in FIG. 5. Accordingly, its corresponding I/O circuit can be disposed opposite the other memory array from the I/O circuit 106 shown in FIG. 5.

In some embodiments, the arrangements 300 to 500 (shown in FIGS. 3 to 5, respectively) can be utilized to form a memory array (and its corresponding circuits) along a single layer. The term “layer,” as used herein, can refer to a single semiconductor substrate, a single wafer, a single metallization layer disposed over a semiconductor substrate, or any processing layer. For example, the transistors of the memory array, WL driver, I/O circuit, and controllers can be formed as one of the following transistor structures: a gate-all-around (GAA) transistor, a nanosheet transistor, a FinFET, a planar transistor, or the like, over a semiconductor substrate. It, however, should be understood that the present disclosure further includes arrangements that can be utilized to form a memory array across different layers vertically spaced from one another, which will be discussed as follows.

FIGS. 6, 7, 8, and 9 illustrate various layouts or arrangements, 600, 700, 800, and 900, of the ROM cells of the memory array 102, respectively, in accordance with various embodiments. In general, each of the arrangements 600 to 900 includes respective floorplans for forming a plural number of n-type ROM cells and a plural number of p-type ROM cells across multiple levels over a substrate, according to various embodiments of the present disclosure. It should be understood that the arrangements of FIGS. 6-9 are merely provided for illustrative purposes and are not intended to limit the scope of the present disclosure.

In FIG. 6, the memory array 102 (or its floorplan) can be divided into array sections 102A and 102B, where the corresponding I/O sections are not shown for clarity. The array section 102A, with its ROM cells formed in n-type, is formed at a lower level (or layer) over a substrate; and the array section 102B, with its ROM cells formed in p-type, is formed at an upper level (or layer) over the substrate. In some embodiments, transistors forming the ROM cells of the array sections 102A-B are configured with a complementary field effect transistor (CFET) structure. For example, the transistors of the array section 102A have their components (e.g., channels, source/drain structures, gate structures, etc.) formed in the lower layer, while the transistor of the array section 102B have their components (e.g., channels, source/drain structures, gate structures, etc.) formed in the upper layer.

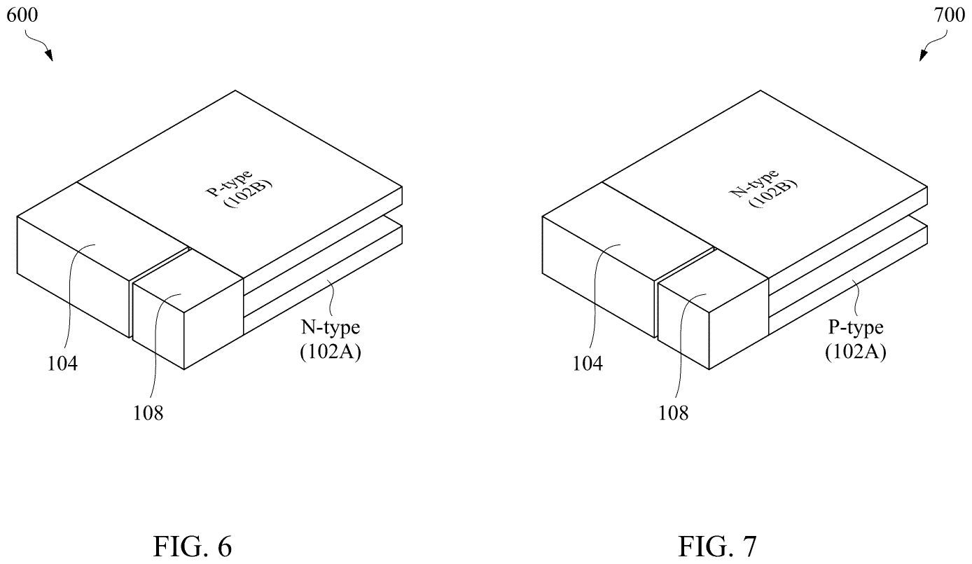

In FIG. 7, the memory array 102 (or its floorplan) can be divided into array sections 102A and 102B, where the corresponding I/O sections are not shown for clarity. The array section 102A, with its ROM cells formed in p-type, is formed at a lower level (or layer) over a substrate; and the array section 102B, with its ROM cells formed in n-type, is formed at an upper level (or layer) over the substrate. In some embodiments, transistors forming the ROM cells of the array sections 102A-B are configured with a complementary field effect transistor (CFET) structure. For example, the transistors of the array section 102A have their components (e.g., channels, source/drain structures, gate structures, etc.) formed in the lower layer, while the transistor of the array section 102B have their components (e.g., channels, source/drain structures, gate structures, etc.) formed in the upper layer.

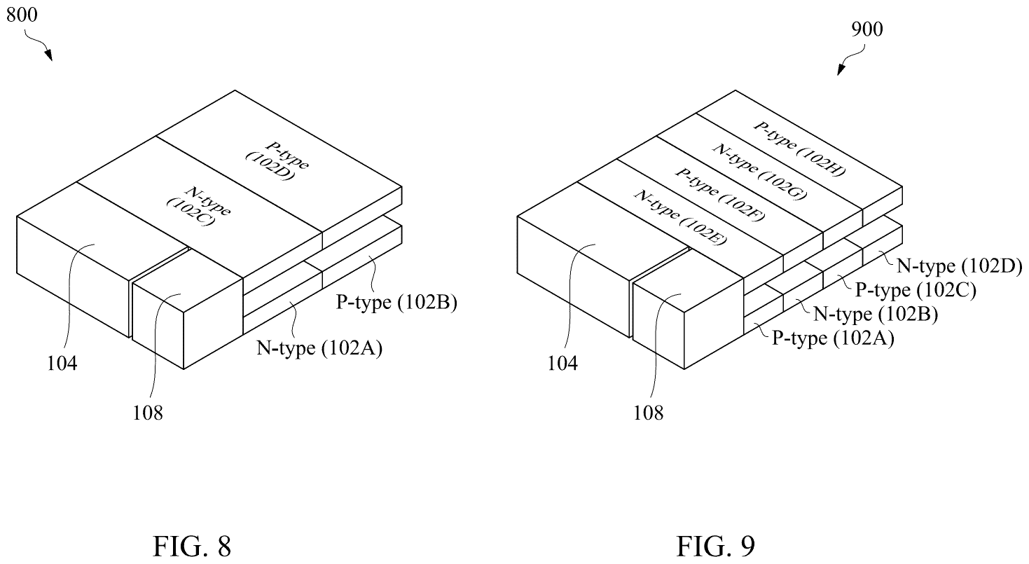

In FIG. 8, the memory array 102 (or its floorplan) can be divided into array sections 102A, 102B, 102C, and 102D, where the corresponding I/O sections are not shown for clarity. The array section 102A, with its ROM cells formed in n-type, is formed at a lower level (or layer) over a substrate; the array section 102B, with its ROM cells formed in p-type, is formed at the lower level (or layer); the array section 102C, with its ROM cells formed in n-type, is formed at an upper level (or layer) over the substrate; and the array section 102D, with its ROM cells formed in p-type, is formed at the upper level (or layer). In some embodiments, transistors forming the ROM cells of the array sections 102A-D are configured with a complementary field effect transistor (CFET) structure. For example, the transistors of the array sections 102A-B have their components (e.g., channels, source/drain structures, gate structures, etc.) formed in the lower layer, while the transistor of the array sections 102C-D have their components (e.g., channels, source/drain structures, gate structures, etc.) formed in the upper layer.

In FIG. 9, the memory array 102 (or its floorplan) can be divided into array sections 102A, 102B, 102C, 102D, 102E, 102F, 102G, and 102H, where the corresponding I/O sections are not shown for clarity. The array section 102A, with its ROM cells formed in p-type, is formed at a lower level (or layer) over a substrate; the array section 102B, with its ROM cells formed in n-type, is formed at the lower level (or layer); the array section 102C, with its ROM cells formed in p-type, is formed at the lower level (or layer); the array section 102D, with its ROM cells formed in n-type, is formed at the lower level (or layer); the array section 102E, with its ROM cells formed in n-type, is formed at an upper level (or layer) over the substrate; the array section 102F, with its ROM cells formed in p-type, is formed at the upper level (or layer); the array section 102G, with its ROM cells formed in n-type, is formed at the upper level (or layer); and the array section 102H, with its ROM cells formed in p-type, is formed at the upper level (or layer). In some embodiments, transistors forming the ROM cells of the array sections 102A-H are configured with a complementary field effect transistor (CFET) structure. For example, the transistors of the array sections 102A-D have their components (e.g., channels, source/drain structures, gate structures, etc.) formed in the lower layer, while the transistor of the array sections 102E-H have their components (e.g., channels, source/drain structures, gate structures, etc.) formed in the upper layer.

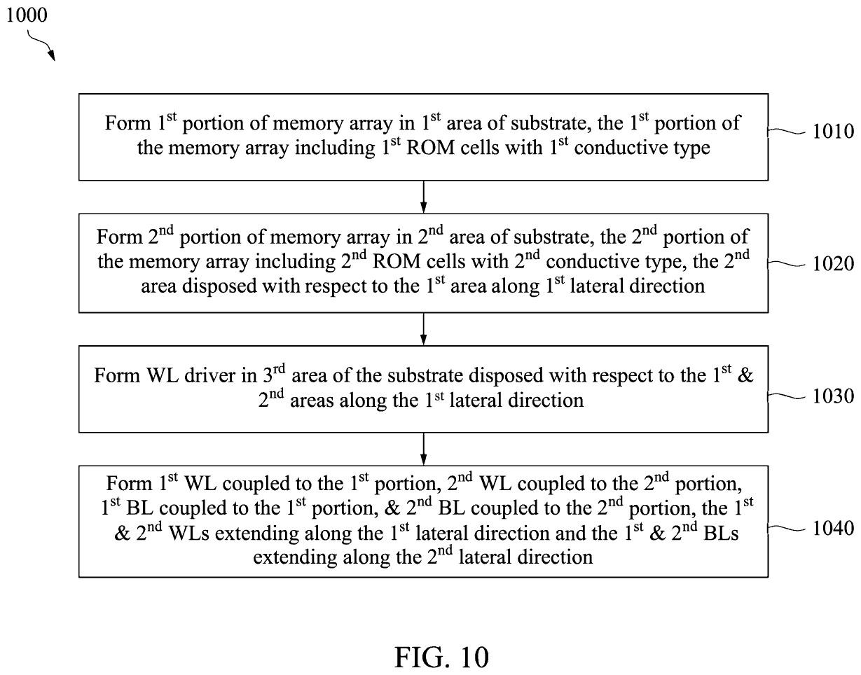

FIG. 10 illustrates a flow chart of an example method 1000 for forming a memory device (e.g., including a memory array and its corresponding circuits), in accordance with various embodiments of the present disclosure. In some embodiments, the memory device can be formed based on the arrangements shown above with respect to FIGS. 3-9. Accordingly, the following discussion of the method 1000 may refer to some of the above figures. It should be noted that the method 1000 as shown in FIG. 10 is merely an example, and is not intended to limit the present disclosure. Thus, it is understood that the order of the operations of the method 1000 of FIG. 10 can be changed, for example, additional operations may be provided before, during, and after the method 1000, and that some operations may only be described briefly herein.

The method 1000 starts with operation 1010 of forming a first portion of a memory array in a first area on a substrate. In some embodiments, the first portion of the memory array comprises a plurality of first read only memory (ROM) cells, and each of the plurality of first ROM cells comprises a first transistor that has a first conductive type. In the example of FIG. 3, the first portion of the memory array can include memory sections 102A to 102C and 102G to 102I. Such different memory sections of the first portion may be disposed in the first area that has multiple areas physically spaced from each other along the Y-direction. In the example of FIG. 4, the first portion of the memory array can include memory sections 102E to 102H. Such different memory sections of the first portion may be disposed in the first area that has multiple areas physically abutted to each other along the Y-direction. In the example of FIG. 5, the first portion of the memory array can include memory sections 102C-D and 102G-H. Such different memory sections of the first portion may be disposed in the first area that has multiple areas physically spaced from each other along the Y-direction.

The method 1000 continues to operation 1020 of forming a second portion of the memory array in a second area on the substrate arranged with respect to the first area along a first lateral direction. In some embodiments, the second portion of the memory array comprises a plurality of second ROM cells, and each of the plurality of second ROM cells comprises a plurality of second transistors that have a second conductive type. In the example of FIG. 3, the second portion of the memory array can include memory sections 102D to 102F. Such different memory sections of the second portion may be disposed in the second area that is interposed between the multiple areas of the first area along the Y-direction. In the example of FIG. 4, the second portion of the memory array can include memory sections 102A to 102DH. Such different memory sections of the second portion may be disposed in the second area physically abutted to the first area along the Y-direction. In the example of FIG. 5, the second portion of the memory array can include memory sections 102A-B and 102E-F. Such different memory sections of the second portion may be disposed next to or between the multiple areas of the first area along the Y-direction.

The method 1000 continues to operation 1030 of forming a word line driver in a third area on the substrate arranged with respect to the first and second areas along the first lateral direction. In the example of FIGS. 3 to 5, the word line driver may be included in or integrated with the WL circuit 104. In some embodiments, the word line driver can be operatively coupled to each of the first portion of the memory array and the second portion of the memory array. Alternative stated, the word line driver can be operatively shared by the first portion of the memory array and the second portion of the memory array.

The method 1000 continues to operation 1040 of forming a first word line electrically coupling the word line driver to the first portion of the memory array, a second word line electrically coupling the word line driver to the second portion of the memory array, a first bit line electrically coupled to the first portion of the memory array, and a second bit line electrically coupled to the second portion of the memory array. In some embodiments, the first word line and the second word line extend along the first lateral direction, and the first bit line and the second bit line extend along a second lateral direction perpendicular to the first lateral direction. Further, the first word line can be coupled to respective gate terminals of the first ROM cells, the second word line can be coupled to respective gate terminals of the second ROM cells, the first bit line can be coupled to respective source or drain terminals of the first ROM cells, and the second bit line can be coupled to respective source or drain terminals of the second ROM cells.

In one aspect of the present disclosure, a memory device is disclosed. The memory device includes a plurality of first memory cells formed in a plurality of first areas on a substrate, each of the plurality of first memory cells comprising a first transistor that has a first conductive type; a plurality of second memory cells formed in a plurality of second areas on the substrate, each of the plurality of second memory cells comprising a second transistor that has a second conductive type; a plurality of first access lines extending along a first lateral direction, each of the first access lines connected to either a group of the first memory cells in the first areas or a group of the second memory cells in the second areas; and a plurality of second access line extending along a second lateral direction perpendicular to the first lateral direction, each of the second access lines connected to each memory cell in a corresponding one of the first areas or in a corresponding one of the second areas. The first areas and the second areas are arranged along the first lateral direction.

In another aspect of the present disclosure, a memory device is disclosed. The memory device includes a first portion of a memory array comprising a plurality of first memory cells, each of the plurality of first cells comprising a first transistor with a first conductive type and electrically coupled to a first word line and a first bit line; and a second portion of the memory array comprising a plurality of second memory cells, each of the plurality of second memory cells comprising a second transistor with a second conductive type and electrically coupled to a second word line and a second bit line. The first word line and second word line extend along a first lateral direction, and the first bit line and second bit line extend along a second lateral direction perpendicular to the first lateral direction. The first portion of the memory array and the second portion of the memory array are disposed next to each other along the first lateral direction.

In yet another aspect of the present disclosure, a method for forming memory devices is disclosed. The method includes forming a first portion of a memory array in a first area on a substrate, wherein the first portion of the memory array comprises a plurality of first read only memory (ROM) cells, each of the plurality of first ROM cells comprising a first transistor that has a first conductive type. The method includes forming a second portion of the memory array in a second area on the substrate, wherein the second portion of the memory array comprises a plurality of second ROM cells, each of the plurality of second ROM cells comprising a second transistor that has a second conductive type. The method includes forming a word line driver in a third area of the substrate operatively coupled to both of the first and second portions of the memory array. In some embodiments, the first area, the second area, and the third area are arranged along a first lateral direction.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a plurality of first memory cells formed in a plurality of first areas on a substrate, each of the plurality of first memory cells comprising a first transistor that has a first conductive type;
a plurality of second memory cells formed in a plurality of second areas on the substrate, each of the plurality of second memory cells comprising a second transistor that has a second conductive type;
a plurality of first access lines extending along a first lateral direction, each of the first access lines connected to either a group of the first memory cells in the first areas or a group of the second memory cells in the second areas; and
a plurality of second access line extending along a second lateral direction perpendicular to the first lateral direction, each of the second access lines connected to each memory cell in a corresponding one of the first areas or in a corresponding one of the second areas;
wherein the first areas and the second areas are arranged along the first lateral direction.

2. The memory device of claim 1, wherein the first memory cells and the second memory cells are each a read only memory (ROM) cell.

3. The memory device of claim 1, wherein each of the first areas is interposed between adjacent ones of the second areas along the first lateral direction.

4. The memory device of claim 1, wherein a subset of the first areas are interposed between adjacent subsets of the second areas along the first lateral direction.

5. The memory device of claim 1, wherein the first areas are disposed next to the second areas along the first lateral direction.

6. The memory device of claim 1, further comprising:
a plurality of first input/output (I/O) transistors having the first conductive type; and
a plurality of second I/O transistors having the second conductive type.

7. The memory device of claim 6, wherein the first I/O transistors are formed in a plurality of third areas on the substrate, and the second I/O transistors are formed in a plurality of fourth areas on the substrate.

8. The memory device of claim 7, wherein each of the third areas is disposed next to a corresponding one of the first areas along a second lateral direction perpendicular to the first lateral direction, and each of the fourth areas is disposed next to a corresponding one of the second areas along the second lateral direction.

9. The memory device of claim 8, further comprising:
a plurality of first peripheral transistors having the first conductive type formed in a plurality of fifth areas on the substrate; and
a plurality of second peripheral transistors having the second conductive type formed in a plurality of sixth areas on the substrate.

10. The memory device of claim 9, wherein each of the third areas is interposed between a corresponding one of the first areas and a corresponding one of the fifth areas along the second lateral direction, and each of the fourth areas is interposed between a corresponding one of the second areas and a corresponding one of the sixth areas along the second lateral direction.

11. A memory device, comprising:
a first portion of a memory array comprising a plurality of first memory cells, each of the plurality of first cells comprising a first transistor with a first conductive type and electrically coupled to a first word line and a first bit line; and
a second portion of the memory array comprising a plurality of second memory cells, each of the plurality of second memory cells comprising a second transistor with a second conductive type and electrically coupled to a second word line and a second bit line;
wherein the first word line and second word line extend along a first lateral direction, and the first bit line and second bit line extend along a second lateral direction perpendicular to the first lateral direction; and
wherein the first portion of the memory array and the second portion of the memory array are disposed next to each other along the first lateral direction.

12. The memory device of claim 11, wherein the first memory cells and the second memory cells are each a read only memory (ROM) cell.

13. The memory device of claim 11, further comprising:
a third portion of the memory array comprising a plurality of third memory cells, each of the plurality of third memory cells comprising a third transistor with the first conductive type and electrically coupled to a third word line and the first bit line.

14. The memory device of claim 13, wherein the third portion of the memory array is disposed next to the first portion of the memory array along the second lateral direction.

15. The memory device of claim 11, further comprising:
a fourth memory portion of the array comprising a plurality of fourth memory cells, each of the plurality of fourth memory cells comprising a fourth transistor that has the second conductive type and electrically coupled to a fourth word line and the second bit line.

16. The memory device of claim 15, wherein the fourth portion of the memory array is disposed next to the second portion of the memory array along the second lateral direction.

17. The memory device of claim 11, wherein a plural number of the first portions of the memory array and a plural number of the portions of the second memory array are alternately arranged to each other along the first lateral direction.

18. The memory device of claim 11, wherein a plural number of the first portions of the memory array abut onto each other along the first lateral direction and a plural number of the second portions of the memory array abut onto each other along the first lateral direction, and the plural number of the first portions of the memory array and the plural number of the second portions of the memory array are arranged to each other along the first lateral direction.

19. A method for forming a memory device, comprising:
forming a first portion of a memory array in a first area on a substrate, wherein the first portion of the memory array comprises a plurality of first read only memory (ROM) cells, each of the plurality of first ROM cells comprising a first transistor with a first conductive type;
forming a second portion of the memory array in a second area on the substrate, wherein the second portion of the memory array comprises a plurality of second ROM cells, each of the plurality of second ROM cells comprising a second transistor with a second conductive type; and
forming a word line driver in a third area of the substrate operatively coupled to both of the first and second portions of the memory array;
wherein the first area, the second area, and the third area are arranged along a first lateral direction.

20. The method of claim 19, further comprising:
forming a first word line electrically coupled to the first portion of the memory array, wherein the first word line extends along the first lateral direction;
forming a second word line electrically coupled to the second portion of the memory array, wherein the second word line extends along the first lateral direction;
forming a first bit line electrically coupled to the first portion of the memory array, wherein the first bit line extends along a second lateral direction perpendicular to the first lateral direction; and
forming a second bit line electrically coupled to the second portion of the memory array, wherein the second bit line extends along the second lateral direction.
